(19) United States
(12) Patent Application Publication
(10) Pub. No.: US 2022/0351942 A1
(43) Pub. Date: Nov. 3, 2022

(54) SEMICONDUCTOR PROCESSING APPARATUS AND METHOD

(71) Applicant: Piotech Inc., Shenyang (CN)

(72) Inventors: Zhuo Wang, Shenyang (CN); Ren Zhou, Shenyang (CN); Saiqian Zhang, Shenyang (CN)

(21) Appl. No.: 17/620,881

(22) PCT Filed: Jun. 1, 2020
(86) PCT No.: PCT/CN2020/093782

§ 371 Date: Dec. 20, 2021

(30) Foreign Application Priority Data
Jul. 24, 2019 (CN) 201910671631.9

(51) Int. Cl. H01J 37/32

(52) U.S. Cl. CPC H01J 37/32183; H01J 37/32568; H01J 37/32541

(57) ABSTRACT

This application provides a plate for a semiconductor processing apparatus, the plate including a first electrode and a second electrode, where the first electrode is selectively coupled to a first ground terminal via a first switch, the second electrode is selectively coupled to a second ground terminal via a second switch, and the first electrode and the second electrode are electrically isolated from each other.

### BACKGROUND OF THE INVENTION

### 1. Field of the Invention

This application generally relates to a semiconductor processing apparatus, and more specifically, to a semiconductor processing apparatus with a tunable radio frequency loop.

### 2. Description of the Related Art

Plasma processing is used in the manufacturing of integrated circuits, photo masks, plasma display, and solar technology. In the manufacturing of an integrated circuit, a wafer is processed by a plasma cavity through, for example, etching, plasma enhanced chemical vapor deposition (PECVD), or plasma enhanced physical vapor deposition (PEPVD). For a more miniature integrated circuit, the control of processing parameters such as plasma energy spectrum, plasma energy radial distribution, plasma density, and plasma density radial distribution needs to be more precise. Especially, the plasma density determines the deposition rate and etching rate on a wafer surface. The plasma density radial distribution and the plasma energy radial distribution affect the uniformity of deposition and etching more significantly. A known semiconductor processing apparatus is provided with an upper electrode and a lower electrode, between which plasma can be generated. However, with the known configuration, it is still not easy to implement precise control, or even the freedom of plasma adjustment is limited.

Therefore, it is necessary to develop a semiconductor processing apparatus or radio frequency component that can provide different radio frequency control strategies to meet the freedom of the process design.

### SUMMARY OF THE INVENTION

In an aspect, this application provides a plate for a semiconductor processing apparatus, the plate including a first electrode and a second electrode, where the first electrode is selectively coupled to a first ground terminal via a first switch, the second electrode is selectively coupled to a second ground terminal via a second switch, and the first electrode and the second electrode are electrically isolated from each other.

In some embodiments, the plate further includes a carrying surface for carrying a wafer, where the first electrode and the second electrode are located below the carrying surface.

In some embodiments, the first electrode is defined by a first radius, and the second electrode is defined by a second radius and a third radius, and the third radius is greater than the first radius and the second radius. The first electrode and the second electrode are located in the same plane or in different planes.

In some embodiments, the first electrode is defined by a first radius, the second lower electrode is defined by a second radius, and the first electrode and the second electrode are located in different planes. According to an embodiment of this application, the first radius and the second radius are approximately equal.

In some embodiments, the first electrode and the second electrode are arranged concentrically. In some other embodiments, at least one of the first electrode and the second electrode is a block in a circular electrode or an annular electrode, and the circular electrode or the annular electrode includes a plurality of blocks.

In some embodiments, at least one of the first electrode and the second electrode includes a mesh structure.

In another aspect, this application provides a semiconductor processing apparatus, including the plate according to an embodiment of this application. The semiconductor processing apparatus further includes a second plate including a third electrode, where the third electrode is electrically coupled to a radio frequency generating and matching device.

In some embodiments, the semiconductor processing apparatus further includes: a first feedback component configured to provide a first feedback signal to the radio frequency generating and matching device based on a signal received from the first electrode; and a second feedback component configured to provide a second feedback signal to the radio frequency generating and matching device based on a signal received from the second electrode.

In still another aspect, this application provides a method for manufacturing a ground electrode for a semiconductor processing apparatus, the method including: providing a plate body; and forming a first electrode and a second electrode electrically isolated from each other in the plate body in the following manner: (1) sintering the first electrode and the second electrode separately into the plate body; or (2) molding at one time the first electrode and the second electrode by using a method of braiding combination and pressing them into the plate body.

In some embodiments, sintering the first electrode and the second electrode separately into the plate body includes: forming the first electrode and the second electrode in the same plane of the plate body by sintering. In some other embodiments, sintering the first electrode and the second electrode separately into the plate body includes: forming the first electrode and the second electrode in different planes of the plate body by sintering.

In yet another aspect, this application provides a method for operating the semiconductor processing apparatus according to an embodiment of this application, the method including: for first processing, controlling the first switch to couple the first electrode to the first ground terminal; and for second processing, controlling the second switch to couple the second electrode to the second ground terminal. In some embodiments, the method further includes: for third processing, controlling the first switch and the second switch to couple the first electrode and the second electrode respectively to the first ground terminal and the second ground terminal.

Details of one or more examples of this application are set forth in the following drawings and description. Other features, objectives, and advantages become obvious according to the description, drawings, and claims.

### BRIEF DESCRIPTION OF THE DRAWINGS

The following drawings are mentioned and included in the content disclosed in this specification:

FIG. 1 is a schematic block diagram of an exemplary radio frequency component according to an embodiment of this application.

FIG. 1A is a schematic structural diagram of an exemplary feedback/control apparatus according to an embodiment of this application.

FIG. 2 is a schematic diagram of a configuration of an exemplary ground electrode according to an embodiment of this application.

FIG. 2A is a schematic diagram of an exemplary circular electrode according to an embodiment of this application.

FIG. 2B is a schematic diagram of an exemplary annular electrode according to an embodiment of this application.

FIG. 3 is a schematic diagram of an exemplary semiconductor processing apparatus according to an embodiment of this application.

FIG. 4 is a schematic diagram of another exemplary semiconductor processing apparatus according to an embodiment of this application.

FIG. 5 is a flowchart of an exemplary method for manufacturing a ground electrode for a semiconductor processing apparatus according to an embodiment of this application.

FIG. 6 is a flowchart of an exemplary method for operating a semiconductor processing apparatus according to an embodiment of this application.

By convention, the drawings are only used to illustrate non-limiting and non-exhaustive examples. The components in the drawings do not have to be actual sizes, and the features illustrated in the drawings may not be drawn to scale. Therefore, for clarity, the size of the features can be enlarged or reduced as required. In addition, for clarity, the embodiments illustrated in the drawings may be simplified. Therefore, the drawings may not illustrate all components of a given device or apparatus. Finally, the same reference numbers may be used throughout the specification and drawings to indicate the same features.

### PREFERRED EMBODIMENT OF THE PRESENT INVENTION

Hereinafter, the present invention will be described more fully with reference to the drawings, and specific exemplary embodiments are shown through examples. However, the claimed subject matter can be implemented in many different forms. Therefore, the construction of the claimed subject matter covered or applied for is not limited to any exemplary specific embodiments disclosed in this specification; and the exemplary specific embodiments are only examples. Likewise, the present invention aims to provide a properly broad category for the claimed subject matter that is applied for or covered. In addition, for example, the claimed subject matter can be embodied as a method, apparatus, or system. Therefore, specific embodiments may take the form of, for example, hardware, software, firmware, or any combination of these (known not as software).

The term “in one embodiment” or “according to an embodiment” used in this specification does not necessarily refer to the same specific embodiment, nor does it mean that the claimed technical solution needs to include all the features described in the embodiment. In this specification, the use of “in other (some/given) embodiments” or “according to other (some/given) embodiments” used herein does not necessarily refer to different specific embodiments. The objective is, for example, that the claimed subject matter includes all or part of a combination of exemplary embodiments.

The terms “including” and “comprising” in this specification are used in an open-ended manner, and therefore should be interpreted as “including, but not limited to . . . ” The term “coupled” in this specification should be understood to encompass “directly connected” and “connected via one or more intermediate components.” The meanings of “upper” and “lower” in this specification are not limited to the relationship directly presented by the diagrams, and should include descriptions with clear correspondence, such as “left” and “right”, or the opposite of “upper” and “lower.” The term “wafer” in this specification should be understood as being interchangeable with terms such as “die,” “chip,” “substrate,” “silicon wafer,” “substrate base” and the like. This specification uses some terms to refer to specific system components. As those skilled in the art understand, different companies may use different names to refer to the system components.

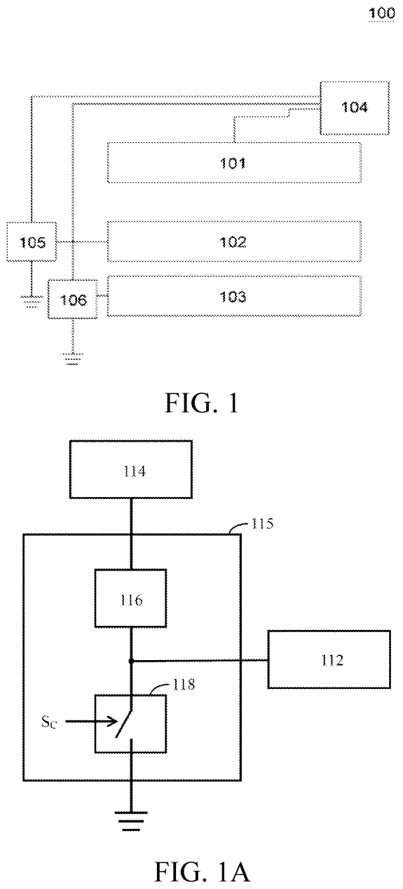

FIG. 1 is a schematic diagram of a radio frequency component 100 according to some embodiments of this application. The radio frequency component 100 includes a first electrode 101 and a plurality of second electrodes 102 and 103 in a cavity (for example, a processing cavity, not shown) of a semiconductor processing apparatus, and a radio frequency generating and matching device 104. Although one first electrode and two second electrodes are shown in FIG. 1, those skilled in the art understand that the radio frequency component 100 may include more first electrodes and/or more second electrodes. FIG. 1 is only for illustrative purposes, and does not limit the actual size, shape, and relative position of each component.

In the example in FIG. 1, the radio frequency generating and matching device 104 is electrically coupled (for example, connected by a coaxial cable) to the first electrode 101 to provide a radio frequency signal. The second electrodes 102 and 103 are electrically coupled to the radio frequency generating and matching device 104 via feedback/control apparatuses 105 and 106 respectively. The feedback/control apparatuses 105 and 106 are configured to: receive one or more sensed signals from the second electrodes 102 and 103 respectively, generate a corresponding plurality of feedback signals accordingly, and provide the feedback signals to the radio frequency generating and matching device 104. The feedback/control apparatuses 105 and 106 may further be configured as switches for selectively electrically coupling the second electrodes 102 and 103 to corresponding ground terminals or disconnecting the second electrodes 102 and 103 from corresponding ground terminals. The ground terminals to which the second electrodes 102 and 103 are coupled may be the same ground point or different ground points. In this application, the first electrode 101 may also be referred to as a “radio frequency electrode,” and the second electrodes 102 and 103 may also be referred to as “ground electrodes.”

In some embodiments, the first electrode 101 may be an upper electrode, and the second electrodes 102 and 103 may be lower electrodes. In some other embodiments, the first electrode 101 may be a lower electrode, and the second electrodes 102 and 103 may be upper electrodes. Generally, the upper electrode is arranged at a top portion of the cavity. Although FIG. 1 does not show the structure of the cavity, a typical cavity is provided with a chamber defined by a top portion, a bottom portion, and a sidewall portion. The top portion is usually provided with a complex intake manifold, gas distributor, gas channel, and shower head. In a typical configuration, the upper electrode is included in the structure of the shower head. The top portion of the cavity or the shower head is electrically coupled to the radio frequency generating and matching device 104 to enable the upper electrode to receive a signal from a radio frequency source.

The lower electrode is configured in a wafer support base. Although not shown in FIG. 1, a typical wafer support base is connected to the bottom portion of the cavity to enable the wafer to be supported at a certain height in the chamber. A plasma region may be formed between the upper electrode and the wafer support base including the lower electrode. The wafer support base may include a carrying surface used for carrying a wafer. The lower electrode is located below the carrying surface.

Although not shown, the radio frequency generating and matching device 104 may include a radio frequency generator and a radio frequency matcher. In an embodiment, the radio frequency generator in the radio frequency generating and matching device 104 may include a low-frequency radio frequency source, a high-frequency radio frequency source, or a combination of both, and the radio frequency matcher in the radio frequency generating and matching device 104 may include a low-frequency dedicated matching network, a high-frequency dedicated matching network, or a combination of both. The matching network includes one or more capacitors, one or more inductors, and some electronic components, and detailed composition of the matching network is not described herein. According to different processing, the selection of low-frequency or high-frequency radio frequency operations is known, and details are not described herein again. The radio frequency generating and matching device 104 is configured to: receive one or more feedback signals provided by the feedback/control apparatuses 105 and 106, and adjust an output frequency of the low-frequency or high-frequency radio frequency source and/or one or more variable electronic components in the matching network, for example, variable capacitors, or other variable components in the radio frequency circuit components, so as to control features of the plasma in the chamber. In some embodiments, the radio frequency generating and matching device 104 may be configured to receive one or more feedback signals from the first electrode 101. In some other embodiments, one or more of the feedback/control apparatuses 105 and 106 do not provide a feedback signal to the radio frequency generating and matching device 104.

In addition, according to different objectives, the feedback/control apparatus in this application may be used to determine various operations associated with the second electrode(s), for example, determine whether the second electrode(s) is (are) grounded, whether to adjust the related variable electronic component(s) or the power applied to the second electrode(s).

FIG. 1A is a schematic structural diagram of an exemplary feedback/control apparatus 115 according to an embodiment of this application. The feedback/control apparatus 115 may be an example of the feedback/control apparatus 105 or 106 in FIG. 1. The feedback/control apparatus 115 may include a feedback component 116 and a switch 118. The feedback component 116 generates a feedback signal based on the signal received from the ground electrode 112 (for example, the second electrode 102 or 103 shown in FIG. 1), and provides the feedback signal to the radio frequency generating and matching device 114 (for example, the radio frequency generating and matching device 104 shown in FIG. 1). In some embodiments, the feedback component 116 directly provides the signal received from the ground electrode 112 to the radio frequency generating and matching device 114. In some embodiments, the feedback/control apparatus 115 does not include the feedback component 116, that is, the feedback/control apparatus 115 does not provide a feedback signal to the radio frequency generating and matching device 114.

Under the control of a control signal S_{C}, the switch 118 selectively couples the ground electrode 112 to the ground terminal or disconnects the ground electrode from the ground terminal. The control signal S_{C} may be based at least in part on the signal received from the ground electrode 112, or at least in part on the signal received from other ground electrode(s) or radio frequency electrode(s), or at least in part on the process requirements of the processing being or to be performed. The control signal S_{C} may be generated by hardware or software. The method for generating a control signal based on some signals or parameters is well known to those skilled in the art, and therefore details are not described herein again. In some embodiments, an impedance network composed of components such as one or more resistors, one or more capacitors, and one or more inductors may be included between the ground electrode 112 and the ground terminal. The impedance network may provide a fixed impedance or a variable impedance in the radio frequency loop (for example, through a variable capacitor).

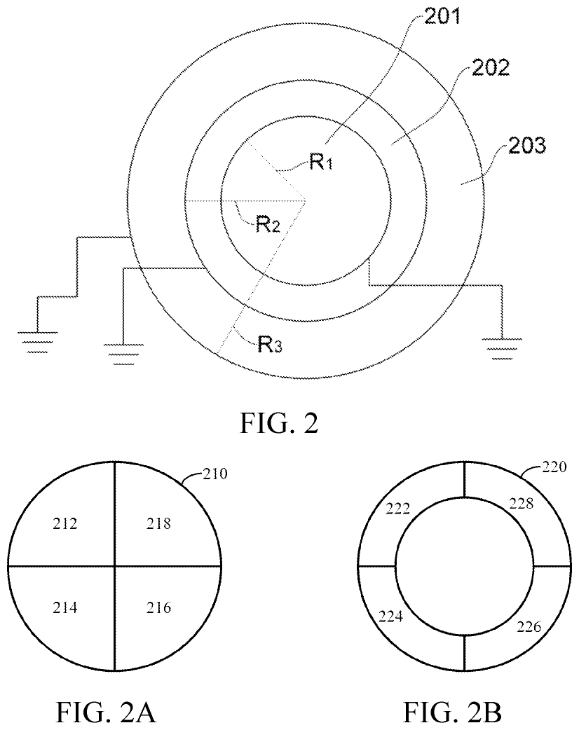

FIG. 2 is a schematic diagram of a configuration of an exemplary ground electrode according to an embodiment of this application (a feedback/control apparatus is omitted). This schematic diagram is a top view of the ground electrode. Although a specific quantity of electrodes is shown in FIG. 2, those skilled in the art understand that the configuration of the ground electrode of this application may include fewer or more electrodes.

The configuration of the ground electrode shown in this embodiment includes a first electrode 201, a second electrode 202, and a third electrode 203. In some embodiments, the first electrode 201, the second electrode 202, and the third electrode 203 are arranged concentrically. The first electrode 201 is a circular electrode defined by a first radius R₁. The second electrode 202 is defined by at least a second radius R₂. The third electrode 203 is defined by at least a third radius R₃. The second radius R₂ is greater than the first radius R₁ but less than the third radius R₃. In an embodiment, the second electrode 202 is a circular electrode; and in another embodiment, the second electrode 202 may be an annular electrode defined by a first inner diameter and the second radius R₂, and the first inner diameter may be greater than, equal to, or less than the first radius In an embodiment, the third electrode 203 is a circular electrode; and in another embodiment, the third electrode 203 may be another annular electrode defined by a second inner diameter and the third radius R₃, and the second inner diameter may be greater than, equal to, or less than the second radius R₂.

In some embodiments, the first electrode 201, the second electrode 202, and the third electrode 203 may be located at the same level (that is, in the same plane). In the embodiments, the second electrode 202 and the second electrode 203 are annular electrodes, and the inner diameter of the second electrode 202 is greater than or equal to the first radius R₁, and the inner diameter of the third electrode 203 is greater than or equal to the second radius R₂. In some other embodiments, the first electrode 201, the second electrode 202, and the third electrode 203 may be at different levels (that is, in different planes), and related examples are provided below. The first electrode 201, the second electrode 202, and the third electrode 203 are electrically isolated from each other (for example, an insulating material is used between the electrodes, or the electrodes are spaced apart from each other). As shown in the figure, each of the first electrode 201, the second electrode 202, and the third electrode 203 may be selectively connected to a ground terminal respectively (feedback/control apparatus(es) is (are) omitted).

In the example of FIG. 2, the ground electrode may be a circular electrode or an annular electrode. In other embodiments, the ground electrode may be a block in the circular electrode or annular electrode. FIG. 2A and FIG. 2B respectively are schematic diagrams of an exemplary circular electrode 210 and an annular electrode 220 including a plurality of blocks according to an embodiment of this application. Although FIG. 2A and FIG. 2B show a specific quantity of blocks divided in a specific manner, those skilled in the art understand that the circular electrode 210 and the annular electrode 220 may include fewer or more blocks divided in other ways.

The circular electrode 210 includes blocks 212, 214, 216, and 218. The annular electrode 220 includes blocks 222, 224, 226, and 228. In some embodiments, the blocks 212, 214, 216, and 218 are electrically isolated from each other by insulating materials, and therefore may be grounded independently. Similarly, in some embodiments, the blocks 222, 224, 226, and 228 are electrically isolated from each other by insulating materials, and therefore may be grounded independently. For example, the second electrode 202 shown in FIG. 1 may be a block 212, and the third electrode 203 may be a block 214 or another circular or annular electrode or a block in another circular or annular electrode.

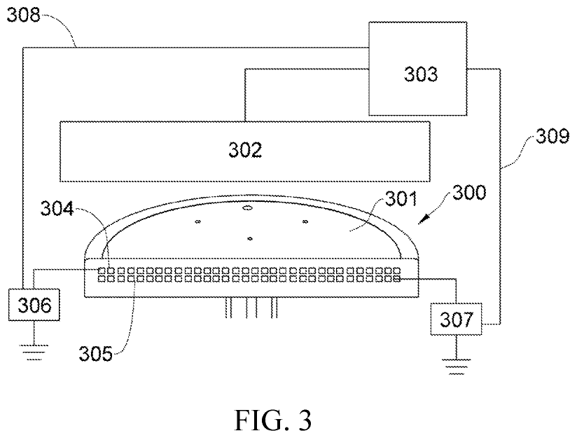

FIG. 3 is a schematic diagram of an exemplary semiconductor processing apparatus according to an embodiment of this application. In the example of FIG. 3, the ground electrode is the lower electrode, which is arranged in the wafer support base. Although a processing cavity is not shown, it should be understood that the wafer support base is mounted in the processing cavity. The wafer support base herein includes a plate 300 provided with a wafer carrying surface 301 for carrying a wafer undergoing various processes. An upper electrode 302 is located at the top portion of the cavity. In an embodiment, the upper electrode 302 is included in a shower head located at the top portion of the cavity. For example, the upper electrode 302 may be a cover or housing of the shower head. The upper electrode 302 is electrically coupled to the radio frequency generating and matching device 303 to receive a radio frequency source. A circuit composition of the radio frequency generating and matching device is the same as that of the radio frequency generating and matching device 104 shown in FIG. 1, and therefore details are not described herein again. The radio frequency generating and matching device 303 may be arranged at the top portion of the cavity or outside the cavity. Alternatively, the radio frequency generating and matching device 303 is electrically coupled to one or more lower electrodes. Alternatively, in a possible embodiment, the radio frequency generating and matching device 303 may be electrically coupled to both the upper electrode and the lower electrode. The composition and combination of the radio frequency generating and matching device may have various changes and are not limited to the description herein. In some embodiments, the plate 300 may further include one or more heating elements.

The wafer support base shown in FIG. 3 is provided with a plurality of lower electrodes. In this embodiment, the plate 300 is embedded with two lower electrodes, namely, a first lower electrode 304 and a second lower electrode 305. The two are located below the wafer carrying surface 301 and are structurally independent of each other (that is, not in contact with each other and do not constitute electrical conduction). The first lower electrode 304 is located below the wafer carrying surface 301 but above the second lower electrode 305. The first lower electrode 304 and the second lower electrode 305 have approximately the same diameter and extend to an area approximate to the wafer carrying surface 301. In other embodiments, the first lower electrode 304 may have a diameter greater or smaller than that of the second lower electrode 305. The first lower electrode 304 and the second lower electrode 305 are arranged concentrically. Herein, the first lower electrode 304 and the second lower electrode 305 are mesh electrodes, and may be formed into the plate 300 by manufacturing means of sintering and pressing. The grid density of the first lower electrode 304 may be the same as or different from that of the second lower electrode 305. It should be understood that the first lower electrode 304 and the second lower electrode 305 may also have other structures, and the structure of the first lower electrode 304 may be the same as or different from that of the second lower electrode 305.

The first lower electrode 304 and the second lower electrode 305 are electrically coupled to a first feedback/control apparatus 306 and a second feedback/control apparatus 307 respectively. The first feedback/control apparatus 306 is configured to have an appropriate circuit composition to receive a sensed signal from the first lower electrode 304 and generate a first feedback signal accordingly. Similarly, the second feedback/control apparatus 307 is configured to have an appropriate circuit composition to receive a sensed signal from the second lower electrode 305 and generate a second feedback signal accordingly. The sensed signal is related to radio frequency power received by each lower electrode (304 or 305) from the upper electrode 302, so that the feedback signal can reflect the features of the plasma in the chamber. The first feedback/control apparatus 306 is in communication connection with the radio frequency generating and matching device 303 via a first feedback path 308, thereby providing the first feedback signal to the radio frequency generating and matching device 303. Similarly, the second feedback/control apparatus 307 is in communication connection via a second feedback path 309 and provides the second feedback signal to the radio frequency generating and matching device 303. In addition, the first feedback/control apparatus 306 and the second feedback/control apparatus 307 are further configured to be capable of selectively electrically coupling the first lower electrode 304 and the second lower electrode 305 to corresponding ground terminals. In addition, although not shown, the first feedback path 308 and the second feedback path 309 may be respectively electrically connected to low-frequency and high-frequency control parts of the radio frequency generating and matching device 303 to implement different processing corresponding to low frequency and high frequency.

The radio frequency generating and matching device 303 is configured to: receive the first feedback signal and/or the second feedback signal, and adjust the plasma based on the feedback signal. The radio frequency generating and matching device 303 may further include a controller for signal processing and outputting. In a possible embodiment, the radio frequency generator (for example, a high-frequency generator or a low-frequency generator) in the radio frequency generating and matching device 303 may adjust a radio frequency output frequency according to instructions of the controller. Alternatively, the radio frequency matcher (for example, a high-frequency matcher or a low-frequency matcher) in the radio frequency generating and matching device 303 may adjust a variable capacitance value according to instructions of the controller to obtain an appropriate matching impedance.

In some possible embodiments, the radio frequency generating and matching device 303 may further include other circuit modules, such as an impedance controller composed of a bandpass filter and/or a notch filter, which may be formed by connecting one or more capacitors, one or more inductors, and one or more variable capacitors. The impedance controller may be configured to be included in the feedback/control apparatus (306 or 307), the radio frequency generating and matching device 303, the controller, or a circuit independent of the foregoing components. One or more impedance controllers may be configured to be electrically coupled to the first lower electrode 304 or the second lower electrode 305 and/or the upper electrode 302. Accordingly, the controller controls the radio frequency generator, the radio frequency matcher and/or the impedance controller based on the first feedback signal or the second feedback signal, thereby achieving the objective of adjusting the plasma.

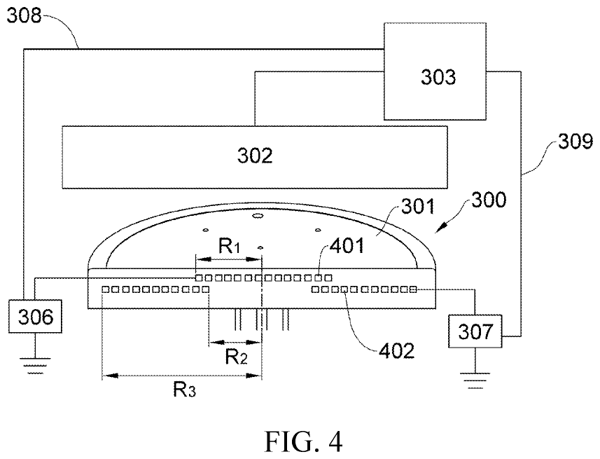

The ground electrodes provided in this application may have different sizes, shapes, materials, embedding depths or grid densities. FIG. 4 is a schematic diagram of another exemplary semiconductor processing apparatus according to an embodiment of this application. The difference from the embodiment in FIG. 3 is the configuration of the lower electrode. The same components as those in FIG. 3 are represented with the same reference numerals, details of which are not described herein again. The example of FIG. 4 includes a first lower electrode 401 and a second lower electrode 402. The two are still structurally independent of each other. The first lower electrode 401 is located below the wafer carrying surface 301 but above the second lower electrode 402. Although only a cross-sectional view is shown, the first lower electrode 401 is a circular lower electrode defined by a first radius R₁, and the second lower electrode 402 is an annular lower electrode defined by a second radius R₂ and a third radius R₃. The total area of the two electrodes is approximately equivalent to the effective region of the wafer carrying surface 301. The third radius R₃ is greater than the first radius R₁ and the second radius R₂, and the second radius R₂ may be less than, equal to, or greater than the first radius R₁. According to the configuration of FIG. 4, the plasma near the center of the wafer may be adjusted based at least on the first lower electrode 401, and the plasma located at the edge of the wafer may be adjusted based at least on the second lower electrode 402. In other possible embodiments, the positions of the first lower electrode 401 and the second lower electrode 402 may be exchanged. In other possible embodiments, the lower electrode closest to the wafer carrying surface 301 may be configured to have electrostatic adsorption capability. More lower electrodes are also feasible. The lower electrodes may be alternatively arranged asymmetrically. That is, a plurality of lower electrodes have different shapes, and some of the lower electrodes are non-rotationally symmetric. For example, the lower electrodes are different sectors.

In summary, the semiconductor processing apparatus provided in this application is provided with a plate embedded with a plurality of ground electrodes electrically isolated from each other, and each of the ground electrodes is selectively coupled to a corresponding ground terminal via a switch. Therefore, according to different processing performed by the semiconductor processing apparatus, different combinations of ground electrodes may be selected to be coupled to ground terminals to form different radio frequency loops, so that the plasma density near different electrode positions can be adjusted, and the thickness of the deposited film or the uniformity of etching can then be controlled.

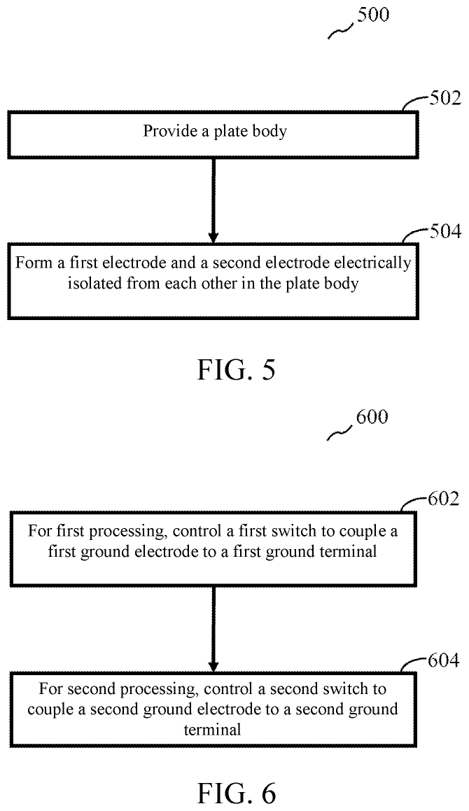

FIG. 5 is a flowchart of an exemplary method 500 for manufacturing a ground electrode (for example, the ground electrodes in the embodiments described in this specification) for a semiconductor processing apparatus according to an embodiment of this application. As shown in FIG. 5, in step 502, a plate body is provided, for example, formed by pressing an aluminum nitride material. In step 504, a first electrode and a second electrode electrically isolated from each other are formed in the plate body. In some embodiments, the first electrode and the second electrode may be separately formed through sintering and pressing. The first electrode and the second electrode may be formed by sintering in the same plane or different planes in the plate body. In some other embodiments, the first electrode and the second electrode may be molded at one time by using a method of braiding combination and pressed into the plate body.

FIG. 6 is a flowchart of an exemplary method 600 for operating a semiconductor processing apparatus (for example, the semiconductor processing apparatus shown in FIG. 3 and FIG. 4) according to an embodiment of this application. According to an embodiment of this application, the semiconductor processing apparatus includes at least a first ground electrode and a second ground electrode, for example, the lower electrodes 304 and 305 shown in FIG. 3 or the lower electrodes 401 and 402 shown in FIG. 4. The first ground electrode is selectively coupled to a first ground terminal via a first switch, the second ground electrode is selectively coupled to a second ground terminal via a second switch, and the first ground electrode and the second electrode are electrically isolated from each other.

In step 602, for first processing performed by the semiconductor processing apparatus, the first switch is controlled to couple the first ground electrode to the first ground terminal, that is, a radio frequency loop of the first processing includes at least the first ground electrode. In step 604, for second processing performed by the semiconductor processing apparatus, the second switch is controlled to couple the second ground electrode to the second ground terminal, that is, a radio frequency loop of the second processing includes at least the second ground electrode. The method 600 may further include: for third processing, controlling the first switch and the second switch to couple the first ground electrode and the second ground electrode to the first ground terminal and the second ground terminal respectively, that is, a radio frequency loop of the third processing includes at least both the first ground electrode and the second ground electrode.

The description in this specification is provided to enable those skilled in the art to implement or use the present invention. Modifications to the present invention are readily apparent to those skilled in the art, and the general principles defined in this specification can be applied to other variations without departing from the spirit or scope of the present invention. Therefore, the present invention is not limited to the examples and designs described in this specification, but is given the widest scope consistent with the principles and novel features disclosed in this specification.

1. A plate for a semiconductor processing apparatus, the plate comprising:
a first electrode; and
a second electrode,
wherein the first electrode is selectively coupled to a first ground terminal via a first switch, the second electrode is selectively coupled to a second ground terminal via a second switch, and the first electrode and the second electrode are electrically isolated from each other.

2. The plate according to claim 1, further comprising a carrying surface for carrying a wafer, wherein the first electrode and the second electrode are located below the carrying surface.

3. The plate according to claim 1, wherein the first electrode is defined by a first radius, the second electrode is defined by a second radius and a third radius, and the third radius is greater than the first radius and the second radius.

4. The plate according to claim 3, wherein the first electrode and the second electrode are located in the same plane.

5. The plate according to claim 3, wherein the first electrode and the second electrode are located in different planes.

6. The plate according to claim 1, wherein the first electrode is defined by a first radius, the second lower electrode is defined by a second radius, and the first electrode and the second electrode are located in different planes.

7. The plate according to claim 6, wherein the first radius and the second radius are approximately equal.

8. The plate according to claim 1, wherein the first electrode and the second electrode are arranged concentrically.

9. The plate according to claim 1, wherein at least one of the first electrode and the second electrode is a block in a circular electrode or an annular electrode, and the circular electrode or the annular electrode comprises a plurality of blocks.

10. The plate according to claim 1, wherein at least one of the first electrode and the second electrode comprises a mesh structure.

11. A semiconductor processing apparatus, comprising:
the plate according to claim 1; and
a second plate comprising a third electrode, wherein the third electrode is electrically coupled to a radio frequency generating and matching device.

12. The semiconductor processing apparatus according to claim 11, further comprising:
a first feedback component configured to provide a first feedback signal to the radio frequency generating and matching device based on a signal received from the first electrode; and
a second feedback component configured to provide a second feedback signal to the radio frequency generating and matching device based on a signal received from the second electrode.

13. A method for manufacturing a ground electrode for a semiconductor processing apparatus, the method comprising:
providing a plate body; and
forming a first electrode and a second electrode electrically isolated from each other in the plate body in the following manner:
sintering the first electrode and the second electrode separately into the plate body; or
molding at one time the first electrode and the second electrode by using a method of braiding combination and pressing the first electrode and the second electrode into the plate body.

14. The method according to claim 13, wherein sintering the first electrode and the second electrode separately into the plate body comprises: forming the first electrode and the second electrode in the same plane of the plate body by sintering.

15. The method according to claim 13, wherein sintering the first electrode and the second electrode separately into the plate body comprises: forming the first electrode and the second electrode in different planes of the plate body by sintering.

16. A method for operating the semiconductor processing apparatus according to claim 11, comprising:
for first processing, controlling the first switch to couple the first electrode to the first ground terminal; and
for second processing, controlling the second switch to couple the second electrode to the second ground terminal.

17. The method according to claim 16, further comprising:
for third processing, controlling the first switch and the second switch to couple the first electrode and the second electrode respectively to the first ground terminal and the second ground terminal.
